(19) United States
(12) Patent Application Publication
(10) Pub. No.: US 2022/0197318 A1
(43) Pub. Date: Jun. 23, 2022

(54) TEMPERATURE ADJUSTMENT APPARATUS

(71) Applicant: SEMES CO., LTD., Cheonan-si (KR)

(72) Inventors: Sang Bo SEO, Yongin-si (KR); Soo Hyang KANG, Pyeongtaek-si (KR); Young Chul SHIN, Paju-si (KR); Chung Woo LEE, Hwaseong-si (KR)

(73) Assignee: SEMES CO., LTD., Cheonan-si (KR)

(21) Appl. No.: 17/554,625

(22) Filed: Dec. 17, 2021

(30) Foreign Application Priority Data
Dec. 21, 2020 (KR) 10-2020-0179983

(51) Int. Cl. G05D 23/19; G05D 23/24; H05B 3/26; H05B 1/02; G01K 7/16

(52) U.S. Cl. CPC G05D 23/1934; G05D 23/24; G05D 23/1917; H05B 2203/005; H05B 1/0233; G01K 7/16; H05B 3/26

(57) ABSTRACT

A temperature adjustment apparatus configured to perform temperature adjustment and control for each fine zone of a substrate, a multi-zone temperature adjustment apparatus including the same, and a multi-zone temperature adjustment type substrate supporting apparatus are proposed. The temperature adjustment apparatus includes a first power source, a second power source, an ammeter connected to the second power source in series and configured to measure a current value of the second power source, a heater inducing a first direction current to dissipate heat energy while being connected to the first power source in series during a heating time period, a temperature sensor inducing a second direction current while being connected to the second power source in series during a sensing time period, and a switch controller controlling connection between the first power source and the heater and connection between the second power source and the temperature sensor.

### CROSS REFERENCE TO RELATED APPLICATION

The present application claims priority to Korean Patent Application No. 10-2020-0179983, filed Dec. 21, 2020, the entire contents of which is incorporated herein for all purposes by this reference.

### BACKGROUND OF THE INVENTION

### Field of the Invention

The present disclosure relates generally to a temperature adjustment apparatus and, more particularly, to a temperature adjustment apparatus configured to perform temperature adjustment and control, and to a multi-zone temperature adjustment apparatus including the same, and a multi-zone temperature adjustment type substrate supporting apparatus.

### Description of the Related Art

A semiconductor (or display) manufacturing process is a process for manufacturing a semiconductor device on a substrate (e.g., wafer). For example, the semiconductor manufacturing process includes processes of exposure, deposition, etching, ion implantation, cleaning, and the like. In a process of processing a substrate by applying thermal energy, such as etching or deposition, it is necessary to control the temperature for each zone of the substrate.

Meanwhile, in accordance with a demand for miniaturization of the semiconductor manufacturing process, temperature control for each fine zone of the substrate is required. In order to perform temperature control for each fine zone, temperature measurement and adjustment of heater output for each fine zone are required.

However, there is a problem in which it is difficult to arrange a temperature measurement apparatus and a heater in a narrow space.

### SUMMARY OF THE INVENTION

Accordingly, the present invention is intended to provide a temperature adjustment apparatus configured to perform temperature measurement and control for each fine zone, and to provide a multi-zone temperature adjustment apparatus including the same, and a multi-zone temperature adjustment type substrate supporting apparatus.

The problem to be solved is not limited thereto, and other problems not mentioned will be clearly understood by those skilled in the art from the subsequent description.

In order to achieve the above objective, according to one aspect of the present disclosure, there is provided a temperature adjustment apparatus including: a first power source; a second power source configured to apply a voltage opposite to a voltage applied from the first power source; an ammeter connected to the second power source in series and configured to measure a current value of the second power source; a heater configured to induce a current in a first direction so as to dissipate heat energy while being connected to the first power source in series during a heating time period; a temperature sensor configured to induce a current in a second direction opposite to the first direction while being connected to the second power source in series during a sensing time period; and a switch controller configured to control connection between the first power source and the heater and connection between the second power source and the temperature sensor.

The heater and the temperature sensor may be connected to each other in parallel through a first common node and a second common node.

The switch controller may include: a heater switch configured to control connection between the first power source and the first common node; a sensor switch configured to control connection between the second power source and the first common node; and a common switch configured to control connection between a common node of the first power source and the second power source and the second common node.

The heater may include: a heater resistor configured to dissipate heat energy by the current in the first direction; and a first diode including an anode connected to the first common node and a cathode connected to the second common node.

The temperature sensor may include: a temperature variable resistor configured such that a resistance valve thereof is variable in response to temperature; and a second diode including an anode connected to the second common node and a cathode connected to the first common node.

The temperature adjustment apparatus may include: an output controller configured to control an output voltage of the first power source on the basis of the current value measured by the ammeter.

According to another embodiment of the present disclosure, there is provided a multi-zone temperature adjustment apparatus including: a first power source; a second power source configured to apply a voltage opposite to a voltage applied from the first power source; an ammeter connected to the second power source in series and configured to measure a current value of the second power source; and a multi-zone temperature adjustment part including temperature adjustment modules configured to individually perform heating and temperature sensing, wherein each of the temperature adjustment module may include: a heater configured to induce a current in a first direction while being connected to the first power source in series during a heating time period; a temperature sensor configured to induce a current in a second direction opposite to the first direction while being connected to the second power source in series during a sensing time period; and a switch controller configured to control connection between the first power source and the heater and connection between the second power source and the temperature sensor.

The heater and the temperature sensor of the temperature adjustment module may be connected to each other in parallel through a row common node and a column common node, the row common node being located in a row to which the temperature adjustment module belongs in row common nodes assigned to each row, and the column common node being located in a column to which the temperature adjustment module belongs in column common nodes assigned to each column.

The switch controller may include: a heater switch array including heater switches configured to control connection between the first power source and the row common nodes; a sensor switch array including sensor switches configured to control connection between the second power source and the row common nodes; and a common switch array including common switches configured to control connection between a common node of the first power source and the second power source and the column common nodes.

The switch controller may be configured to turn on one common switch, which corresponds to a specific column in the common switch array; to perform heating and temperature sensing for temperature adjustment modules corresponding to the specific column; and to turn off the common switch, which corresponds to the specific column, and to turn on one common switch, which corresponds to a next column, thereby to perform heating and temperature sensing of temperature adjustment modules belonging to the next column.

In order to perform the heating and temperature sensing for the temperature adjustment modules belonging to the specific column, the switch controller may be configured to turn on one of the heater switches, which corresponds to a specific row, and to turn off one of the sensor switches, which belongs to the specific row, so as to perform heating of a temperature adjustment module belonging to the specific row of the specific column; and to turn off the heater switch, which corresponds to the specific row, and to turn on the sensor switch, which belongs to the specific row, so as to perform temperature sensing for the temperature adjustment module belonging to the specific row of the specific column; and to perform heating and temperature sensing of a temperature adjustment module belonging to a row following the specific row.

The heater may include: a heater resistor configured to dissipate heat energy by the current in the first direction; and a first diode including an anode connected to the row common node and a cathode connected to the column common node.

The temperature sensor may include: a temperature variable resistor configured such that a resistance valve thereof may be variable in response to temperature; and a second diode including an anode connected to the column common node and a cathode connected to the row common node.

The multi-zone temperature adjustment apparatus may include: an output controller configured to control an output voltage of the first power source on the basis of the current value measured by the ammeter.

According to further embodiment of the present disclosure, there is provided a multi-zone temperature adjustment type substrate supporting apparatus including: a heater plate in which a heater resistor and a temperature variable resistor may be laid, the heater resistor being configured to dissipate heat energy for each of a plurality of temperature adjustment zones and the temperature variable resistor being configured such that a resistor value thereof is variable in response to temperature; a diode block having a first diode and a second diode that may be provided for each of the temperature adjustment zones, the first diode being connected to the heater resistor in series and the second diode being connected to the temperature variable resistor and configured to induce a current in a direction opposite to a direction of the first diode; a power source part including a first power source and a second power source arranged in each of the temperature adjustment zones, the first power source being connected to the heater resistor and the first diode in series during a heating time period and the second power source being connected to the temperature variable resistor and the second diode during a sensing time period; an ammeter connected to the second power source in series and configured to measure a current value of the second power source; a switch controller configured to connect connection between the first power source and the heater resistor and connection between the second power source and the temperature variable resistor; and an output controller configured to control an output voltage of the first power source in response to the current value of the second power source measured by the ammeter.

The heater resistor and the first diode may be respectively connected to the temperature variable resistor and the second diode in parallel through a first common node and a second common node.

The switch controller may include: a heater switch configured to control connection between the first power source and the first common node; a sensor switch configured to control connection between the second power source and the first common node; and a common switch configured to control connection between a common node of the first power source and the second power source and the second common node.

An anode of the first diode may be connected to the first common node and a cathode of the first diode may be connected to the second common node.

The switch controller may be configured to turn on the heater switch and turn off the sensor switch during the heating time period, and to turn off the heater switch and turn on the sensor switch during the sensing time period.

An anode of the second diode may be connected to the second common node and a cathode of the second diode may be connected to the first common node.

According to the embodiment of the present disclosure, the temperature measurement and control with respect to the fine zones can be performed by forming the configuration of the heater and the temperature sensor simply and by controlling operations thereof.

The effect of the present disclosure is not limited to the above description, and other effects not mentioned will be clearly understood by those skilled in the art from the subsequent description.

### BRIEF DESCRIPTION OF THE DRAWINGS

The above and other objectives, features, and other advantages of the present disclosure will be more clearly understood from the subsequent detailed description when taken in conjunction with the accompanying drawings, in which:

FIG. 1 is a view showing an example of a multi-layered heating plate including a macro-zone heater and a micro-zone heater;

FIG. 2 is a view showing temperature adjustment zones in the micro-zone heater according to an embodiment;

FIG. 3 is a circuit diagram of a temperature adjustment apparatus according to an embodiment of the present disclosure;

FIG. 4 is a timing diagram for adjusting and controlling the temperature according to the embodiment of the present disclosure;

FIG. 5 is a view showing a current flow for outputting a heater in the temperature adjustment apparatus;

FIG. 6 is a view showing a current flow for measuring the temperature in the temperature adjustment apparatus;

FIG. 7 is a view showing a temperature adjustment apparatus with an output controller;

FIG. 8 is a flowchart for measuring and controlling the temperature in the temperature adjustment apparatus;

FIG. 9 is a circuit diagram showing a temperature adjustment apparatus with 4 micro-zones;

FIG. 10 is a circuit diagram showing a temperature adjustment apparatus with 16 micro-zones;

FIG. 11 is a view showing a current flow for outputting a heater in the temperature adjustment apparatus with the 16 micro-zones;

FIG. 12 is a view showing a current flow for measuring the temperature in the temperature adjustment apparatus with the 16 micro-zones;

FIG. 13 is a table for controlling each switch in the temperature adjustment apparatus with the 16 micro-zones;

FIGS. 14 and 15 are flowcharts for measuring and controlling the temperature in a multi-zone temperature adjustment apparatus;

FIG. 16 is a block diagram showing a multi-zone temperature adjustment type substrate supporting apparatus according to an embodiment of the present disclosure; and

FIG. 17 is a block diagram showing a multi-zone temperature adjustment type substrate supporting apparatus according to another embodiment of the present disclosure.

### DETAILED DESCRIPTION OF THE INVENTION

Hereinbelow, exemplary embodiments of the present disclosure will be described in detail with reference to the accompanying drawings such that the present disclosure can be easily embodied by one of ordinary skill in the art to which the present disclosure belongs. However, the present disclosure may be changed to various embodiments and the scope and spirit of the present disclosure are not limited to the embodiments described hereinbelow.

In the subsequent description, if it is decided that the detailed description of a known function or configuration related to the present disclosure makes the subject matter of the present disclosure unclear, the detailed description is omitted, and the same reference numerals will be used throughout the drawings to refer to the elements or parts with a same or similar function or operation.

Furthermore, in various embodiments, elements with the same configuration will be described in a representative embodiment by using the same reference numeral, and different configurations from the representative embodiment will be described in other embodiments.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words, such as “between” versus “directly between”, “adjacent” versus “directly adjacent”, etc., used to describe the relationship between elements should be interpreted in a like fashion. It will be further understood that the terms “comprises”, “comprising”, includes, and/or including, when used herein, specify the presence of stated features, integers, steps, operations, elements, and/or components, but do not preclude the presence or addition of one or more other features, integers, steps, operations, elements, components, and/or groups thereof.

In the following description, unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

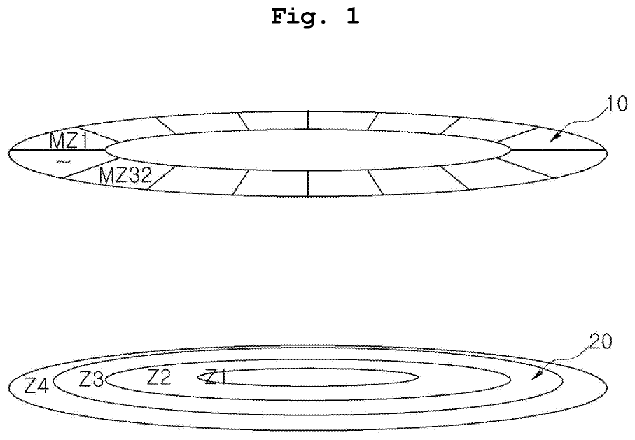

FIG. 1 is a view showing an example of a multi-layered heating plate including a macro-zone heater and a micro-zone heater. In a case in which a substrate (e.g., a wafer) is processed by creating a high-temperature environment like an etching apparatus, temperature distribution may be different for each zone in the substrate. When the temperature distribution is different for each zone in the substrate, properties (e.g., etching profile) are different for each zone in the substrate, resulting in the deterioration of process quality. Therefore, in order to uniformly maintain temperature distribution for the entire region in the substrate, it is necessary to finely control for each region in the substrate.

In general, the temperature of the substrate tends to decrease from the center of the substrate toward the edge thereof. Therefore, as a macro-zone heater 20 shown in FIG. 1, a temperature control method operated by dividing the substrate on a center portion of the substrate into zones of concentric circles may be applied. For example, in a direction from the center to the edge of the substrate, the substrate may be divided into the zones of a first macro-zone Z1, a second macro-zone Z2, a third macro-zone Z3, and a fourth macro-zone Z4.

Particularly, the edge zone of the substrate may tend to be uneven in temperature distribution. When a temperature control zone of the substrate is divided such as the third macro-zone Z3 and the fourth macro-zone Z4 of the edge zone of the macro-zone heater 20, micro-control for each zone may be difficult.

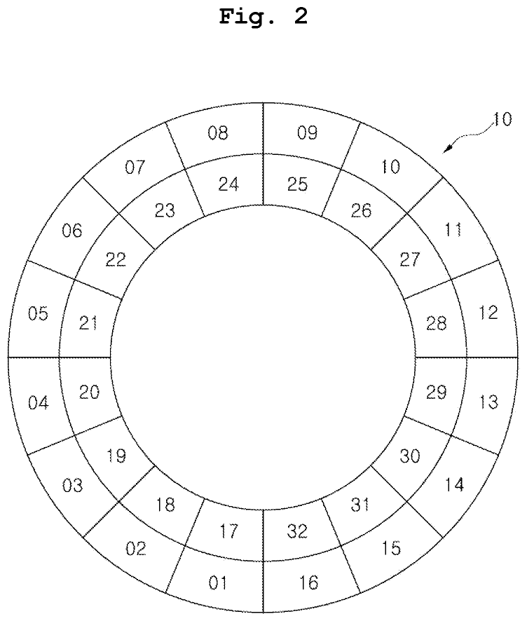

Therefore, a micro-zone heater 10 shown in FIG. 1 may be applied. Referring to FIG. 1, the micro-zone heater 10 is configured to control the temperature by dividing the edge zone of the substrate into a plurality of zones. The micro-zone heater 10 may include 32 micro-zones MZ1 to MZ32 as shown in FIG. 2. The macro-zone heater 20 and the micro-zone heater 10 may be layered to form a single heater assembly.

In order to control the temperature for each of the micro-zones MZ1 to MZ32, a method of measuring the temperature for each of the micro-zones MZ1 to MZ32 and of controlling output of a heater by comparing a value of the measured temperature to a target temperature value may be used. However, in fine zones such as the micro-zone heater 10, it is difficult to arrange a temperature measurement sensor and a temperature control heater. Therefore, the embodiment of the present disclosure provides a temperature adjustment apparatus capable of performing both temperature measurement and temperature control even for a narrow zone.

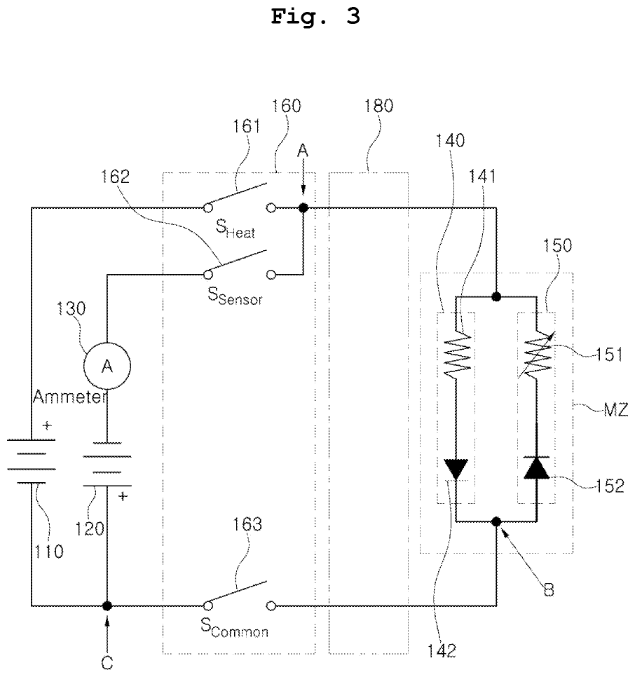

FIG. 3 is a circuit diagram of a temperature adjustment apparatus according to an embodiment of the present disclosure. According to the embodiment of the present disclosure, the temperature adjustment apparatus includes a first power source 110, a second power source 120 applying a voltage opposite to a voltage applied from the first power source 110 (i.e., the first and second power sources 110 and 120 applying voltages with opposite polarities, e.g., the positive polarity and the negative polarity, respectively), an ammeter 130 connected to the second power source 120 in series and measuring a current value of the second power source 120, a heater 140 dissipating heat energy by being connected to the first power source 110 in series during a heating time period and inducing a current I1 in a first direction, a temperature sensor 150 connected to the second power source 120 in series during a sensing time period and inducing a current I2 in a second direction, and a switch controller 160 controlling connection between the first power source 110 and the heater 140 and connection between the second power source 120 and the temperature sensor 150. In some embodiments, the first and second power sources 110 and 120 may be DC (direct current) power sources.

The heater 140 and the temperature sensor 150 are connected to each other in parallel through a first common node A and a second common node B. The heater 140 and the temperature sensor 150 may be connected to each other in parallel to provide a single temperature adjustment zone MZ.

The switch controller 160 includes a heater switch 161 (SHeat), a sensor switch 162 (SSensor), and a common switch 163 (SCommon). The heater switch 161 (SHeat) controls connection between the first power source 110 and the first common node A, the sensor switch 162 (SSensor) controls connection between the second power source 120 and the first common node A, and the common switch 163 (SCommon) controls connection between a common node C of the first power source 110 and the second power source 120 and the second common node B. The switch controller 160 may include a processor or a controller for controlling operation of each switch.

The heater 140 includes a heater resistor 141 and a first diode 142. The heater resistor 141 dissipates heat energy by the current I1 in the first direction, and first diode 142 has an anode connected to the first common node A and a cathode connected to the second common node B.

The temperature sensor 150 includes a temperature variable resistor 151 and a second diode 152. The temperature variable resistor 151 has a resistor value variable in response to the temperature, and the second diode 152 has an anode connected to the second common node B and a cathode connected to the first common node A.

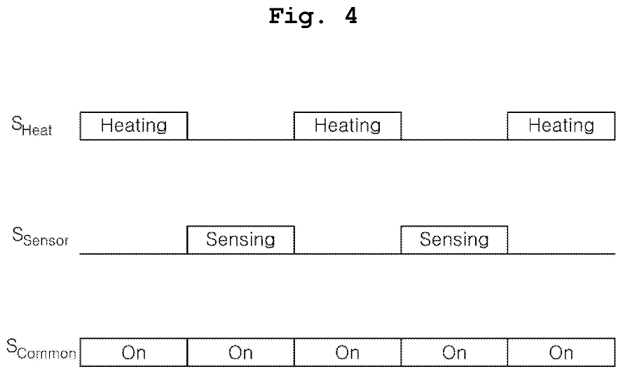

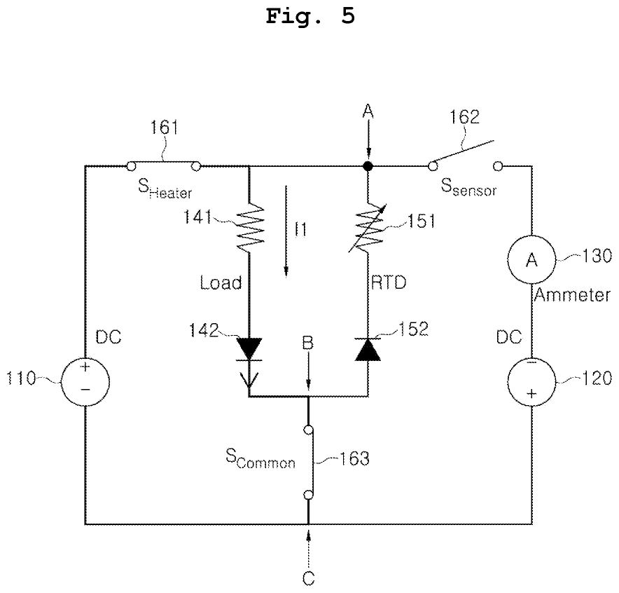

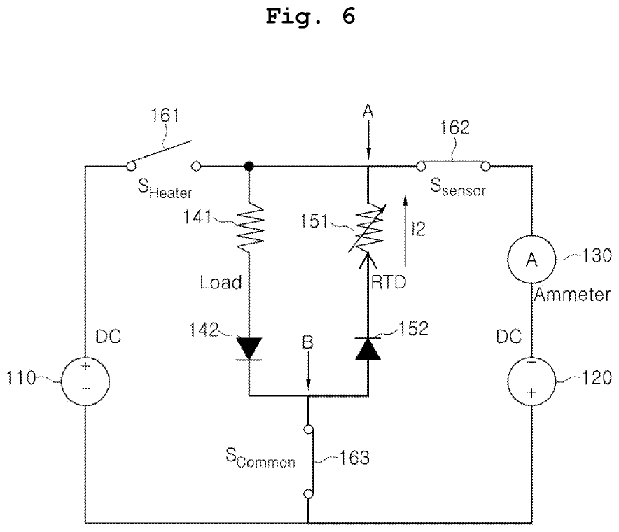

According to the embodiment of the present disclosure, in the heating time period for adjusting the temperature, the first power source 110 and the heater 140 are connected to each other so that heat energy may be dissipated. In the sensing time period for measuring the temperature, the second power source 120 and the temperature sensor 150 are connected to each other, and the temperature may be measured. Specifically, the temperature adjustment and measurement may be performed such that, the switches are selectively turned on and off as shown in FIG. 4, and a current is induced in the first direction (clockwise) in the temperature adjustment as shown in FIG. 5, and a current is induced in the second direction (counterclockwise) in the temperature measurement as shown in FIG. 6.

Specifically, referring to FIG. 4, in the heating time period, the heater switch 161 is turned on and the sensor switch 162 is turned off. As shown in FIG. 5, the current I1 in the first direction (clockwise) is induced to the heater resistor 141 by the first diode 142, and a current flowing to the temperature variable resistor 151 is broken by the second diode 152. Therefore, the current I1 flowing in the heater resistor 141 allows heat energy to be generated and the temperature in the temperature adjustment zone MZ may be increased.

Then, as shown in FIG. 4, the heater switch 161 is turned off and the sensor switch 162 is turned on in the sensing time period. Therefore, as shown in FIG. 6, the current I2 in the second direction (counterclockwise) is induced to the temperature variable resistor 151 by the second diode 152, and a current to the heater resistor 141 is broken by the first diode 142. Therefore, the current I2 flowing through the temperature variable resistor 151 may be measured by the ammeter 130. The temperature variable resistor 151 is a resistor with a resistance value variable in response to the temperature. Since the resistance value of temperature variable resistor 151 is changed, a current value flowing through the temperature variable resistor 151 may be changed. A value of the current flowing through the temperature variable resistor 151 is measured by the ammeter 130 and the temperature is measured through the value of the current measured by the ammeter 130. The measured temperature may affect the voltage of the first power source 110 (or length of heating time period) by being fed back after measurement.

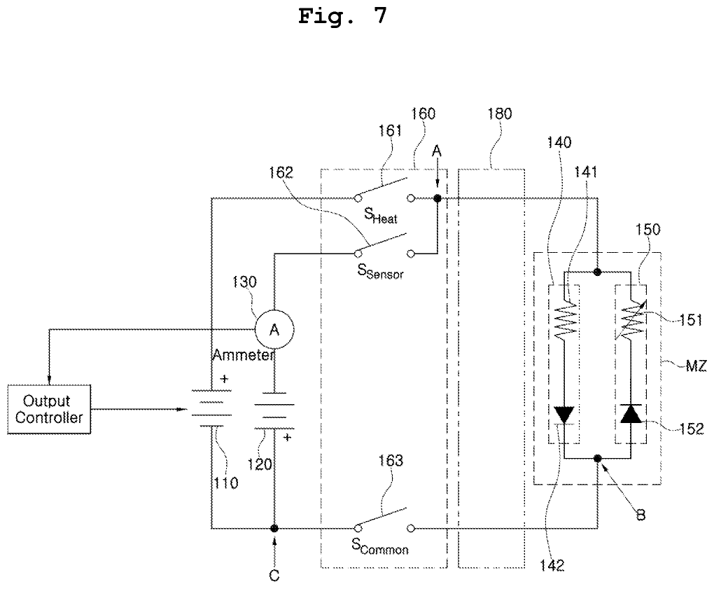

According to the embodiment of the present disclosure, the temperature adjustment apparatus may include an output controller 170. The output controller 170 controls an output voltage of the first power source 110 or the length of the heating time period in response to the value of the current measured by the ammeter 130. As shown in FIG. 7, the output controller 170 may calculate the present temperature in the relevant controlled zone from the value of the current measured by the ammeter 130, and calculate a difference between the present temperature and a target temperature to control the output voltage of the first power source 110. For example, the output controller 170 may increase the output voltage of the first power source 110 when the present temperature is lower than the target temperature. The output controller 170 may reduce the output voltage of the first power source 110 when the present temperature is larger than the target temperature.

As another method of controlling the temperature, the output controller 170 may control the length of the heating time period. For example, the output controller 170 may increase the length of the heating time period when the present temperature is lower than the target temperature. The output controller 170 may reduce the length of the heating time period when the present temperature is larger than the target temperature.

Meanwhile, as shown in FIG. 3, the temperature adjustment apparatus may include a harness 180 as a part thereof. The harness 180 is provided to realize electrical connection between the heater 140, the temperature sensor 150, and the switch controller 160.

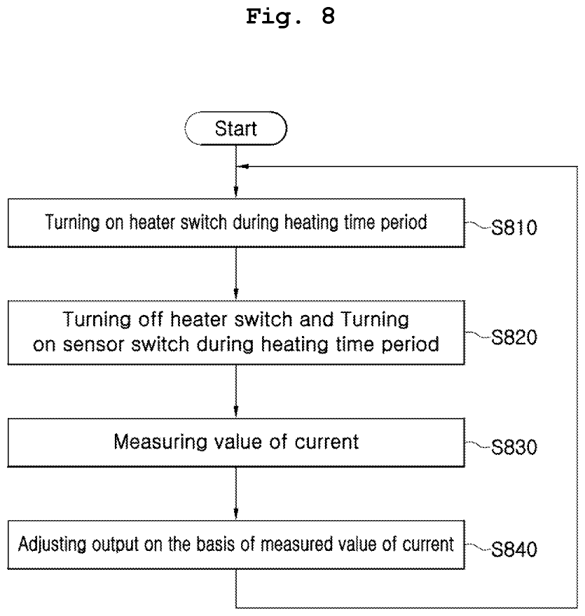

FIG. 8 is a flowchart for measuring and controlling the temperature in the temperature adjustment apparatus. According to the embodiment of the present disclosure, in the temperature adjustment apparatus, a method of measuring and controlling the temperature includes: in the heating time period, turning on the heater switch 161 at S810; in the sensing time period, turning off the heater switch 161 and the sensor switch 162 on at S820; in the sensing time period, measuring the value of the current at S830; and adjusting output on the basis of the value of the measured current at S840.

The temperature adjustment apparatus described with reference to FIGS. 3 to 8 relates to the single temperature adjustment zone, and the temperature adjustment apparatus described above and an operational method thereof may be applied to a temperature adjustment apparatus of a plurality of temperature adjustment zones (micro-zone).

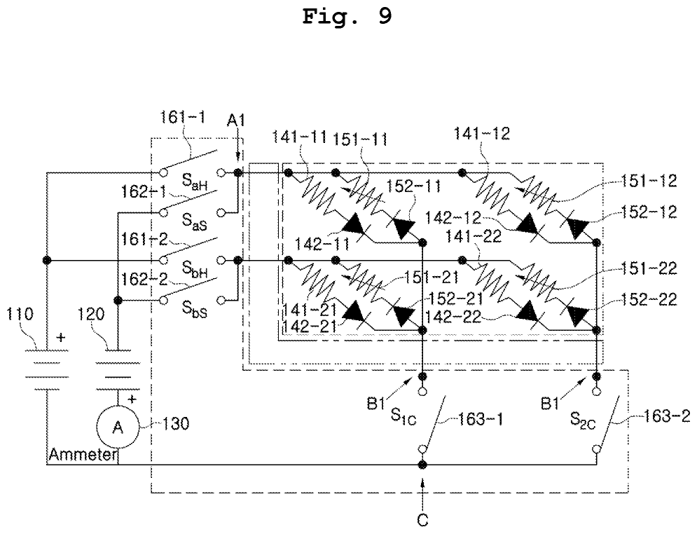

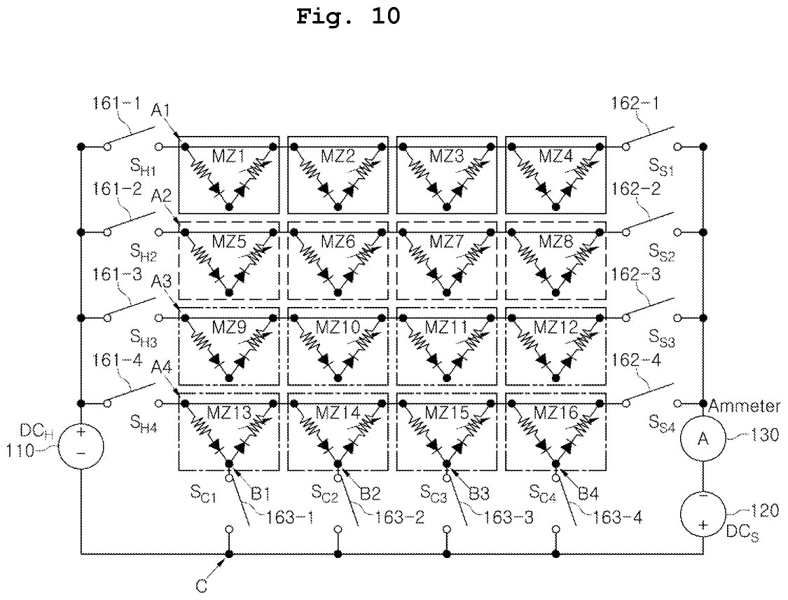

FIG. 9 is a circuit diagram showing a temperature adjustment apparatus with 4 micro-zones. FIG. 10 is a circuit diagram showing a temperature adjustment apparatus with 16 micro-zones. For convenience of description, the temperature adjustment apparatus is described based on 4 and 16 micro-zones, but the present disclosure may be applied to a temperature adjustment apparatus with 32 micro-zones or more. According to an embodiment of the present disclosure, the multi-zone temperature adjustment apparatus includes the first power source 110, the second power source 120 applying a voltage opposite to a voltage of the first power source 110, the ammeter 130 connected to the second power source 120 in series and measuring a voltage of a current of the second power source 120, and a multi-zone temperature adjustment part including the temperature adjustment modules MZ performing heating and temperature sensing. Each of the temperature adjustment modules MZ includes the heater 140, the temperature sensor 150, and the switch controller 160. The heater 140 is connected to the first power source 110 in series in the heating time period to induce the current I1 in the first direction. The temperature sensor 150 is connected to the second power source 120 in series in the sensing time period to induce the current I2 in the second direction opposite to the first direction. The switch controller 160 controls the connection between the first power source 110 and the heater 140 and the connection between the second power source 120 and the temperature sensor 150.

The heater 140 and the temperature sensor 150 of the temperature adjustment module are connected to each other in parallel through a row common node (e.g., A1) of a row (e.g., first row) to which the temperature adjustment module belongs among row common nodes (e.g., A1, A2) each assigned to each row and a column common node (e.g., B1) of a column (e.g., first column) to which the temperature adjustment module belongs among column common nodes (e.g., B1, B2) each assigned to each column.

The switch controller 160 includes a heater switch array, a sensor switch array, and a common switch array. The heater switch array includes heater switches 161 controlling connection between the first power source 110 and the row common nodes (e.g., A1, A2). The sensor switch array includes sensor switches controlling connection between the second power source 120 and the row common nodes (e.g., A1, A2). The common switch array includes common switches 163 controlling connection between the common node C of the first power source 110 and the second power source 120 and the column common nodes (e.g., B1, B2).

In the multi-zone temperature adjustment apparatus as shown in FIGS. 9 and 10, assuming that the temperature adjustment modules are arranged in a 2×2 or 4×4 array, the common switch 163 corresponding to a specific column is turned on and then the heater switch 161 and the sensor switch 162 of the temperature adjustment module located on each row are turned on and off in order. Therefore, the temperature measurement and control are performed, and after the temperature measurement and control of the specific column are completed, a following column proceeds, so that the temperature measurement and control of the temperature adjustment module included in the following column may be performed.

Therefore, the switch controller 160 may turn on a common switch (e.g., S1C, 163-1), which corresponds to a specific column (e.g., first column) in the common switch array; perform heating and temperature sensing for the temperature adjustment modules included in the specific column (e.g., first column); turn off the common switch (e.g., S1C, 163-1), which corresponds to the specific column (e.g., first column); and then turn on a common switch (e.g., S2C, 163-2), which corresponds to a next column (e.g., second column), whereby the heating and temperature sensing for the temperature adjustment modules included in the next column (e.g., second column) may be performed.

In order to perform the heating and temperature sensing for the temperature adjustment modules included in the specific row, the switch controller 160 may perform heating for the temperature adjustment module included in the specific row (e.g., first row) of the specific column (e.g., first column) by turning on a heater switch (e.g., SaH, 161-1), which corresponds to a specific row (e.g., first row) and turning off a sensor switch (e.g., SaS, 162-1), which corresponds to the specific row (e.g., first row), and may perform temperature sensing for the temperature adjustment module included in the specific row (e.g., first row) of the specific column (e.g., first column) by turning on the heater switch (e.g., SaH, 161-1), which corresponds to the specific row (e.g., first row) and turning on the sensor switch (e.g., SaS, 162-1), which corresponds to the specific row (first row), and may perform heating and temperature sensing included in the next row (e.g., second row) of the specific row (e.g., first row).

The heater 140 includes the heater resistor 141 dissipating heat energy by a current I2 in the first direction, and a first diode 142 having an anode connected to a row common node (e.g., A1, A2) and a cathode connected to a column common node (e.g., B1, B2).

Furthermore, the temperature sensor 150 includes the temperature variable resistor 151 changed in a resistance value in response to the temperature, and the second diode 152 having an anode connected to the column common node (e.g., B1, B2) and a cathode connected to the row common node (e.g., A1, A2).

As described above, the output controller 170 may be provided to derive a temperature value from the measured current value to provide an output voltage of the first power source 110.

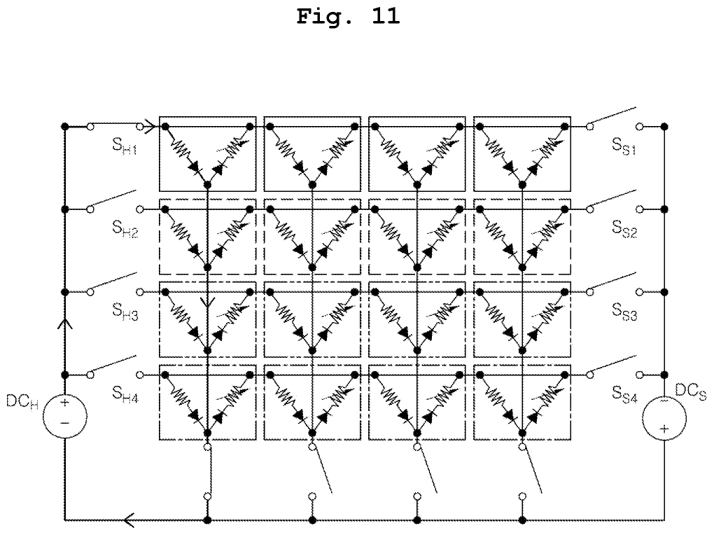

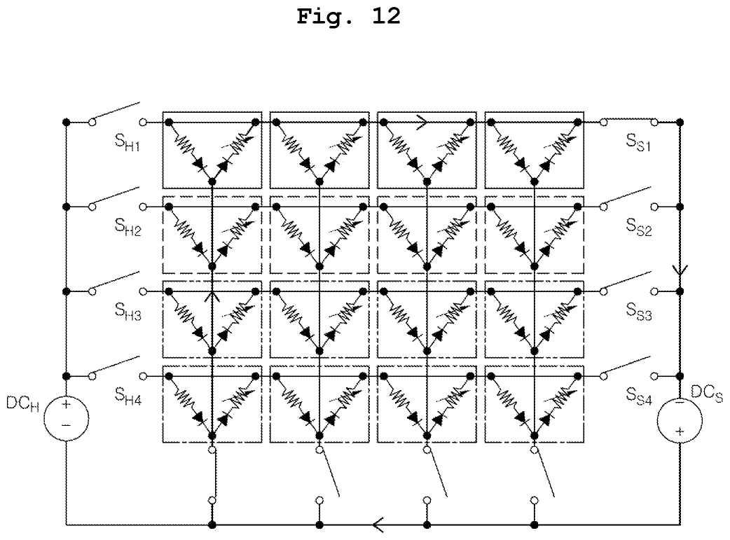

FIG. 11 is a view showing a current flow for heater output in a temperature adjustment apparatus having 16 micro-zones. FIG. 12 is a view showing a current flow for temperature measurement in the temperature adjustment apparatus having 16 micro-zones. Referring to FIG. 11, during the heating time period, the heater switch 161 corresponding to a first row is turned on so that a current I1 in the first direction (clockwise) is induced toward the heater resistor 141 by the first diode 142, and a current flowing toward the temperature variable resistor 151 is broken by the second diode 152. Therefore, the current I1 flowing in the heater resistor 141 allows heat energy to be generated and the temperature in the temperature adjustment zone MZ may be increased.

Then, as shown in FIG. 12, the heater switch 161 is turned off and the sensor switch 162 is turned on in the sensing time period. Therefore, as shown in FIG. 12, the current I2 in the second direction (counterclockwise) is induced to the temperature variable resistor 151 by the second diode 152, and a current to the heater resistor 141 is broken by the first diode 142. Therefore, the current I2 flowing through the temperature variable resistor 151 may be measured by the ammeter 130. The temperature variable resistor 151 is a resistor with a resistance value variable in response to the temperature. Since the resistance value of temperature variable resistor 151 is changed, a current value flowing through the temperature variable resistor 151 may be changed. A value of the current flowing through the temperature variable resistor 151 is measured by the ammeter 130 and the temperature is measured through the value of the current measured by the ammeter 130. The measured temperature may affect the voltage of the first power source 110 (or length of heating time period) by being fed back after measurement.

For other temperature adjustment modules, the temperature measurement and control may be performed as a direction of a current is controlled by controlling a switch with the same principle.

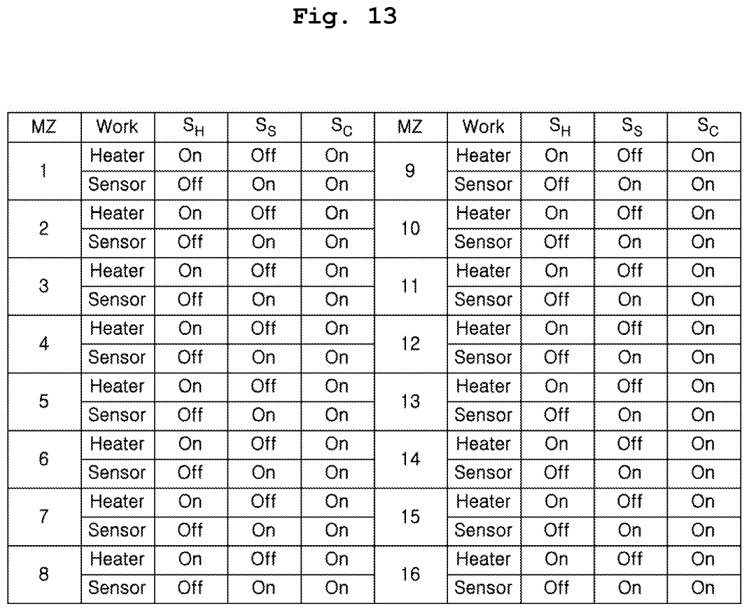

FIG. 13 is a table for controlling each switch in the temperature adjustment apparatus with the 16 micro-zones. As shown in FIG. 13, the switches may be controlled in a method as shown in FIG. 13 to perform the temperature measurement and control of the temperature adjustment module corresponding to each micro-zone MZ. In FIG. 13, “O” indicates that a switch relevant to “O” is turned on, and an empty space indicates that a switch is turned off.

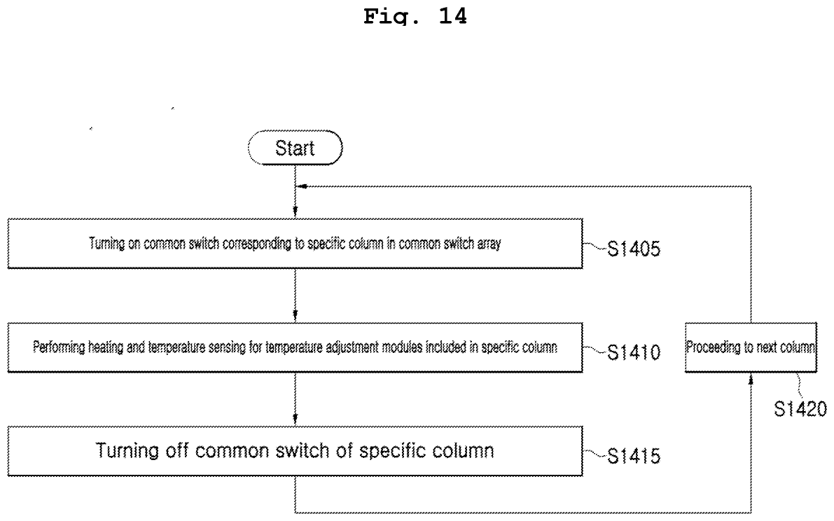

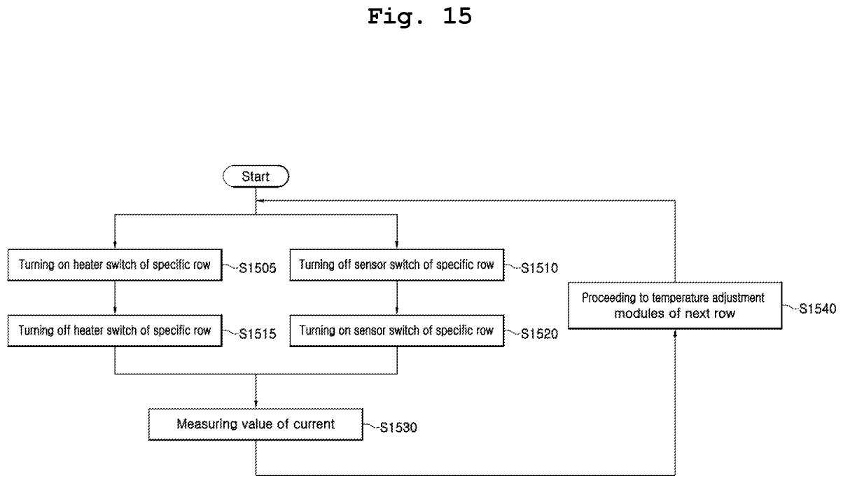

FIGS. 14 and 15 are flowcharts for measuring and controlling the temperature in a multi-zone temperature adjustment apparatus. FIG. is a flowchart showing a method of performing the temperature measurement and control in a row unit. FIG. 15 is a flowchart showing a method of performing the temperature measurement and control in a row unit in each column.

The temperature measurement and control according to the embodiment of the present disclosure includes: turning on the common switch (e.g., 163-1) corresponding to a specific column (e.g., first column) in the common switch array at S1405; performing heating and temperature sensing with respect to temperature adjustment modules included in the specific column (e.g., first column) at S1410; when the temperature measurement and control with respect to all the temperature adjustment modules included in the specific column (e.g., first column) is completed, turning off the common switch (e.g., 163-1) of the specific column (e.g., first column) at S1415; and proceeding to a next column (e.g., second column) and performing the temperature measurement and control with respect to temperature adjustment modules in the next column (e.g., second column) at S1420.

The performing the heating and temperature sensing with respect to the temperature adjustment modules included in the specific column (e.g., first column) at S1410 includes: as shown in FIG. 15, turning on the heater switch (161-1) of the specific row (e.g., first row) at S1505 and turning off the sensor switch (162-1) of the specific row (e.g., first row) at S1510; turning off the heater switch (161-1) of the specific row (e.g., first row) at S1515 and turning on the sensor switch (162-1) of the specific row (first row) at S1520; measuring a current generated by the second power source 120 by using the ammeter 130 at S1530; and proceeding to a next row (e.g., second row) and performing the temperature measurement and control with respect to temperature adjustment modules of the next row (second row) at S1540. The operations in FIG. 15 are performed until when the temperature measurement and control with respect to all the temperature adjustment module in the specific column are completed.

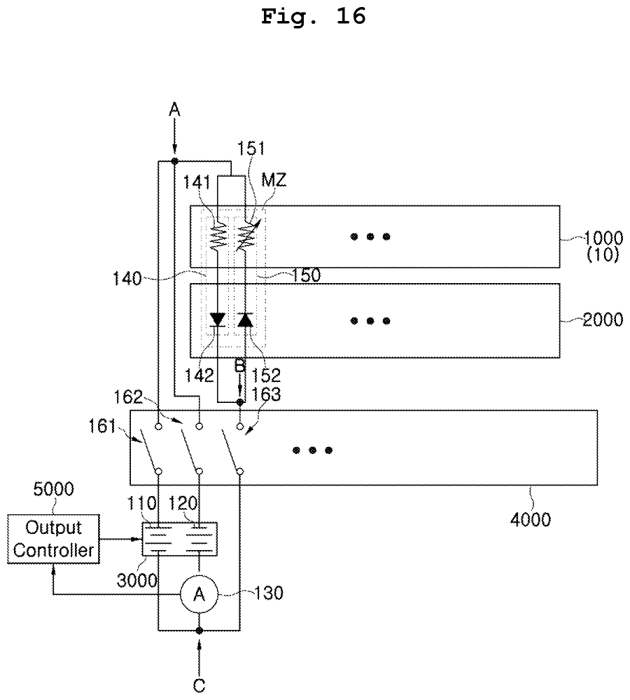

FIG. 16 is a block diagram showing a multi-zone temperature adjustment type substrate supporting apparatus according to an embodiment of the present disclosure. The temperature adjustment apparatus described above may be provided in the substrate support apparatus supporting a substrate to process the substrate.

According to the embodiment of the present disclosure, the multi-zone temperature adjustment type substrate supporting apparatus includes: a heater plate 1000 in which the heater resistor 141 and the temperature variable resistor 151 are laid, the heater resistor 141 dissipating heat energy for each of a plurality of temperature adjustment zones MZ and the temperature variable resistor 151 having a resistance value variable in response to the temperature; a diode block 2000 having the first diode 142 and the second diode 152 that are provided for each of the temperature adjustment zones MZ, the first diode 142 being connected to the heater resistor 141 in series, and the second diode 152 being connected to the temperature variable resistor 151 in series and inducing a current in a direction opposite to a direction of the first diode 142; a power source part 3000 including the first power source 110 and the second power source 120 for each of the temperature adjustment zones MZ, the first power source 110 being connected to the heater resistor 141 and the first diode 142 in series during the heating time period and the second power source 120 connected to the temperature variable resistor 151 and the second diode 152 in series during the sensing time period; the ammeter 130 connected to the second power source 120 in series and measuring a current value of the second power source 120; a switch control block 4000 controlling connection between the first power source 110 and the heater resistor 141 and connection between the second power source 120 and the temperature variable resistor 151; and an output controller 5000 controlling an output voltage of the first power source 110 on the basis of the current value measured by the ammeter 130.

According to the embodiment of the present disclosure, the heater resistor 141 and the first diode 142 may be connected to the temperature variable resistor 151 and the second diode 152 in parallel through the first common node A and the second common node B.

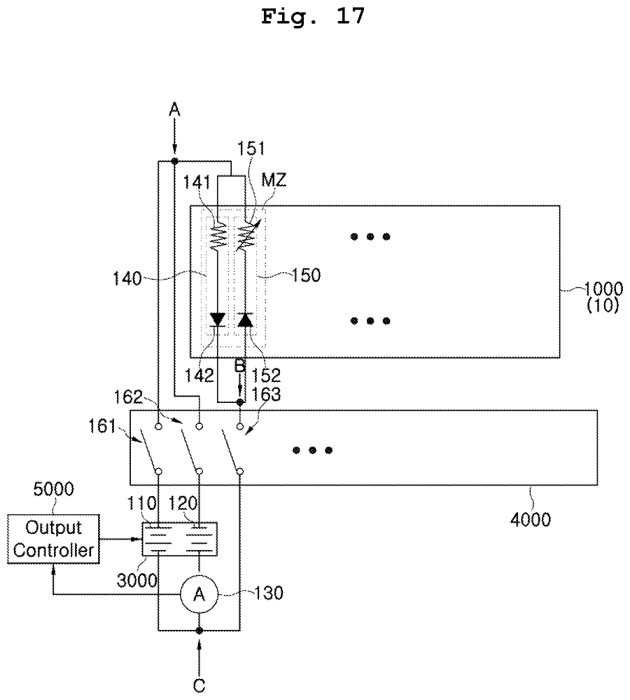

According to the embodiment of the present disclosure, the heater plate 1000 may be provided in an electrostatic chuck supporting a substrate, and the diode block 2000, the power source part 3000, the switch control block 4000, and the output controller 5000 may be provided outside the electrostatic chuck. As shown in FIG. 17, the heater plate 1000 and the diode block 2000 may be provided in the electrostatic chuck together.

According to the embodiment of the present disclosure, the switch controller 160 includes the heater switch 161, the sensor switch 162, and the common switch 163. The heater switch 161 controls connection between the first power source 110 and the first common node A, the sensor switch 162 controls connection between the second power source 120 and the first common node A, and the common switch 163 controls connection between the common node C of the first power source 110 and the second power source 120 and the second common node B.

According to the embodiment of the present disclosure, during the heating time period, the switch controller 160 turns on the heater switch 161 and turns off the sensor switch 162, and during the sensing time period, the switch controller 160 turns off the heater switch 161 and turns on the sensor switch 162.

According to the embodiment of the present disclosure, an anode of the first diode 142 is connected to the first common node A, a cathode of the first diode 142 is connected to the second common node B. Furthermore, an anode of the second diode 152 is connected to the second common node B and a cathode of the second diode 152 is connected to the first common node A.

As described above, in order to perform the temperature measurement and control with respect to a plurality of zones, a plurality of the heater resistors 141 and the first diodes 142, and the temperature variable resistors 151 and the second diodes 152 may be arranged in a shape of array. Furthermore, a plurality of the heater switches 161, the sensor switches 162, and the common switches 163 may be arranged. The temperature measurement and control with respect to the plurality of zones may be performed by the same method as described above with reference to in FIGS. 9 to 15.

Although the preferred embodiments of the present disclosure have been disclosed for illustrative purposes, those skilled in the art will appreciate that various modifications, additions and substitutions are possible, without departing from the scope and spirit of the invention as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

The scope of the present disclosure will be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. A temperature adjustment apparatus comprising:
a first common node;
a first power source selectively connected to the first common node and configured to apply a first voltage with a first polarity to the first common node;
a second power source selectively connected to the first common node and configured to apply, to the first common node, a second voltage with a second polarity opposite to the first polarity of the first voltage;
an ammeter connected to the second power source in series and configured to measure a current value of the second power source;
a heater configured to induce a current in a first direction so as to dissipate heat energy while being connected to the first power source in series during a heating time period;
a temperature sensor configured to induce a current in a second direction opposite to the first direction while being connected to the second power source in series during a sensing time period; and
a switch controller configured to control connection between the first power source and the heater and connection between the second power source and the temperature sensor.

2. The temperature adjustment apparatus of claim 1, further comprising:
a second common node,
wherein the heater and the temperature sensor are connected to each other in parallel between the first common node and the second common node.

3. The temperature adjustment apparatus of claim 2,
wherein the switch controller comprises:
a heater switch configured to control connection between the first power source and the first common node;
a sensor switch configured to control connection between the second power source and the first common node; and
a common switch configured to control connection between the second common node between a common node to which the first power source and the second power source are connected.

4. The temperature adjustment apparatus of claim 3,
wherein the heater comprises:
a heater resistor configured to dissipate heat energy by the current in the first direction; and
a first diode comprising an anode connected to the first common node and a cathode connected to the second common node.

5. The temperature adjustment apparatus of claim 3,
wherein the temperature sensor comprises:
a temperature variable resistor configured such that a resistance valve of the temperature variable resistor is variable in response to temperature; and
a second diode comprising an anode connected to the second common node and a cathode connected to the first common node.

6. The temperature adjustment apparatus of claim 1, further comprising:
an output controller configured to control an output voltage of the first power source on the basis of the current value measured by the ammeter.

7. A multi-zone temperature adjustment apparatus comprising:
a plurality of row common nodes;
a first power source selectively connected to one of the plurality of row common nodes and configured to apply a first voltage with a first polarity to the selected row common node of the plurality of row common nodes;
a second power source selectively connected to one of the plurality of row common nodes and configured to apply, to the elected row common node of the plurality of row common nodes, a second voltage with a second polarity opposite to the first polarity of the first voltage;
an ammeter connected to the second power source in series and configured to measure a current value of the second power source; and
a multi-zone temperature adjustment part comprising a plurality of temperature adjustment modules configured to individually perform heating and temperature sensing,
wherein each of the plurality of temperature adjustment modules comprises:
a heater configured to induce a current in a first direction while being connected to the first power source in series during a heating time period;
a temperature sensor configured to induce a current in a second direction opposite to the first direction while being connected to the second power source in series during a sensing time period; and
a switch controller configured to control connection between the first power source and the heater and connection between the second power source and the temperature sensor.

8. The multi-zone temperature adjustment apparatus of claim 7, further comprising:
a plurality of column common nodes,
wherein each of the plurality of temperature adjustment modules connected to a corresponding one of the plurality of row common nodes and a corresponding one of the plurality of column common nodes, and
wherein in each of the plurality of temperature adjustment modules, the heater and the temperature sensor are connected to each other in parallel between a corresponding row common node of the plurality of row common nodes and a corresponding column common node of the plurality of column common nodes.

9. The multi-zone temperature adjustment apparatus of claim 8,
wherein the switch controller comprises:
a heater switch array comprising a plurality of heater switches configured to control connection between the first power source and the plurality of row common nodes;
a sensor switch array comprising a plurality of sensor switches configured to control connection between the second power source and the plurality of row common nodes; and
a common switch array comprising a plurality of common switches configured to control connection between the plurality of column common nodes and a common node to which the first power source and the second power source are connected.

10. The multi-zone temperature adjustment apparatus of claim 9,
wherein the switch controller is configured to:
turn on a first common switch, which corresponds to a specific column in the plurality of common switches of the common switch array, perform heating and temperature sensing for temperature adjustment modules corresponding to the specific column, and turn off the first common switch, which corresponds to the specific column; and
turn on a second common switch, which corresponds to a next column in the plurality of common switches of the common switch array, thereby to perform heating and temperature sensing of temperature adjustment modules belonging to the next column.

11. The multi-zone temperature adjustment apparatus of claim 10,
wherein, in order to perform the heating and temperature sensing for the temperature adjustment modules belonging to the specific column, the switch controller is configured to turn on a first heater switch of the plurality of heater switches, which corresponds to a specific row, and to turn off a first sensor switch of the plurality of sensor switches, which belongs to the specific row, so as to perform heating of a temperature adjustment module belonging to the specific row of the specific column; and to turn off the first heater switch, which corresponds to the specific row, and to turn on the first sensor switch, which belongs to the specific row, so as to perform temperature sensing for the temperature adjustment module belonging to the specific row of the specific column; and to perform heating and temperature sensing of a temperature adjustment module belonging to a row following the specific row.

12. The multi-zone temperature adjustment apparatus of claim 9,
wherein the heater comprises:
a heater resistor configured to dissipate heat energy by the current in the first direction; and
a first diode comprising an anode connected to the corresponding row common node and a cathode connected to the corresponding column common node.

13. The multi-zone temperature adjustment apparatus of claim 9,
wherein the temperature sensor comprises:
a temperature variable resistor configured such that a resistance valve of the temperature variable resistor is variable in response to temperature; and
a second diode comprising an anode connected to the column common node and a cathode connected to the row common node.

14. The multi-zone temperature adjustment apparatus of claim 7, further comprising:
an output controller configured to control an output voltage of the first power source on the basis of the current value measured by the ammeter.

15. A multi-zone temperature adjustment type substrate supporting apparatus comprising:
a heater plate in which a heater resistor and a temperature variable resistor are laid, the heater resistor being configured to dissipate heat energy for each of a plurality of temperature adjustment zones and the temperature variable resistor being configured such that a resistor value thereof is variable in response to temperature;
a diode block having a first diode and a second diode that are provided for each of the plurality of temperature adjustment zones, the first diode being connected to the heater resistor in series and the second diode being connected to the temperature variable resistor and configured to induce a current in a direction opposite to a direction of the first diode;
a power source part comprising a first power source and a second power source arranged in each of the plurality of temperature adjustment zones, the first power source being connected to the heater resistor and the first diode in series during a heating time period and the second power source being connected to the temperature variable resistor and the second diode during a sensing time period;
an ammeter connected to the second power source in series and configured to measure a current value of the second power source;
a switch controller configured to connect connection between the first power source and the heater resistor and connection between the second power source and the temperature variable resistor; and
an output controller configured to control an output voltage of the first power source in response to the current value of the second power source measured by the ammeter.

16. The multi-zone temperature adjustment type substrate supporting apparatus of claim 15,
wherein the heater resistor and the first diode are respectively connected to the temperature variable resistor and the second diode in parallel between a first common node and a second common node.

17. The multi-zone temperature adjustment type substrate supporting apparatus of claim 16,
wherein the switch controller comprises:
a heater switch configured to control connection between the first power source and the first common node;
a sensor switch configured to control connection between the second power source and the first common node; and
a common switch configured to control connection between the second common node and a common node to which the first power source and the second power source are connected.

18. The multi-zone temperature adjustment type substrate supporting apparatus of claim 17,
wherein an anode of the first diode is connected to the first common node and a cathode of the first diode is connected to the second common node.

19. The multi-zone temperature adjustment type substrate supporting apparatus of claim 17,
wherein the switch controller is configured to:
turn on the heater switch and turn off the sensor switch during the heating time period, and
turn off the heater switch and turn on the sensor switch during the sensing time period.

20. The multi-zone temperature adjustment type substrate supporting apparatus of claim 17,
wherein an anode of the second diode is connected to the second common node and a cathode of the second diode is connected to the first common node.
